(19) United States
(12) Patent Application Publication
(10) Pub. No.: US 2025/0192816 A1
(43) Pub. Date: Jun. 12, 2025

(54) Non-Centrosymmetric Link for a Communication Signal System

(71) Applicant: Christine Marie Kennefick, Reston, VA (US)

(72) Inventor: Christine Marie Kennefick, Reston, VA (US)

(21) Appl. No.: 18/961,526

(22) Filed: Nov. 27, 2024

Related U.S. Application Data
(63) Continuation of application No. 63/607,584, filed on Dec. 8, 2023.

(51) Int. Cl. H04B 1/40; H10N 30/40; H10N 30/85

(52) U.S. Cl. CPC H04B 1/40; H10N 30/40; H10N 30/85

(57) ABSTRACT

A communication link system utilizes a non-centrosymmetric structure of packed tetrahedra that under a load produces uncoupled strain patterns around the tetrahedra. Differing uncoupled strain patterns across crystals in a link can interact with atomic or electronic configurations within a transceiver. The differing uncoupled strain patterns across two crystals can also interact with an incoming wave to move and rearrange charges within the link system to produce an outgoing signal wave whose amplitude and direction increases signal strength at a transceiver. The system is self-powered in that the crystalline piezoelectric link needs no auxiliary power. The piezoelectric link can provide a small supplemental voltage that can be used for another application or can be altered by an incoming wave to aid an outgoing signal.

### FIELD OF THE INVENTION

The present invention relates to tangible communication links that can promote reception and transmission of wave signals. It also relates to piezoelectric structures that can provide a voltage for auxiliary power.

### BACKGROUND OF THE INVENTION

Communication signal loss can occur from a disruption in power, a degradation of the material that receives or transmits a signal, or from an object or another wave that scatters a wave signal. Even as signals move to higher frequencies with increased bandwidth, physical structures can impede these signals. In addition, at smaller wavelengths, the cost of closely spaced ground equipment can impede distribution in rural areas. Even at lower frequencies, signals can be weak or absent due to mountains, buildings, or simply remote terrain.

This invention seeks to overcome the aforementioned causes of signal loss. By itself, the communication link disclosed is self-powered in that it does not need connection to an electric circuit, cable, or power supply. A piezoelectric effect inside the link sustained by a static load can supply a small voltage for another purpose, if desired. The link structure in this invention delocalizes charges that can oscillate to promote a stronger signal reading at a separate transceiver.

### BRIEF SUMMARY OF THE INVENTION

The present invention is a system that comprises a tangible communication link at lattice, granular, and millimeter length scales. The system may have a link that may be a non-centrosymmetric crystalline structure of packed tetrahedra, such as that found in quartz or albite. The packed tetrahedra may have a first region with a first orientation of packed tetrahedra that under one or more loads produces a first pattern of uncoupled strain. A second region with a second orientation of packed tetrahedra under a load may produce a second pattern of uncoupled strain. The link structure may have a third region with a change in orientation of tetrahedra or a fissure between the first and second regions. The communication link system may have an antenna or transceiver that has a configuration of atoms and charges that is a result of an interaction with the first and second patterns of uncoupled strain within the non-centrosymmetric crystalline link of packed tetrahedra. An initial piezoelectric response from a material may provide a voltage for auxiliary power for another application. Separation and delocalization of charges from a piezoelectric response and from patterns of uncoupled strain may provide oscillations, changes in angular momentum, and force fields to produce or alter a signal as output. The signal can be a wave, voltage, or internal matter rearrangement at a microscopic level inside the communication link. A first object of the invention is to enhance signal transmission from separated and delocalized charges at atomic and lattice scale levels from a single self-powered communication link without additional electric circuits attached to the link. It is a second object of the invention to provide a small amount of continuous, reliable, non-battery, and non-fuel power from the same single material structure to power, as an option, an auxiliary device.

### BRIEF DESCRIPTION OF THE DRAWINGS

Reference will be made to the accompanying drawings, which can represent any length scale from atomic to continuum levels.

FIG. 1 is an overview of a structure showing a piezoelectric material under an applied stress and subsequent separation and delocalization of electrons;

FIG. 2 shows an oscillation of electrons under an incoming wave to produce a second outgoing wave;

FIG. 3 shows an outgoing wave under a force field before exiting the device;

FIG. 4 shows a redistribution of charges from a first voltage to produce one or more secondary voltages, and a second load applied to a piezoelectric material.

FIG. 5 shows an interaction between a structure in a material with that in an antenna.

FIG. 6 illustrates a simple embodiment of a material link near an antenna.

FIG. 7 shows one mechanism by which a signal interacts with material geometry at a microscopic level to produce an outgoing wave at an angle.

FIG. 8 shows a material link beneficially directing signals into an antenna.

FIG. 9 shows a material link directing a signal wave away from an antenna.

FIG. 10 shows a plurality of material links, each of which can direct a signal wave into an antenna by itself or in concert with one or more other material links.

FIG. 11 shows a region of uncoupled strain in the vicinity of a non-centrosymmetric structural unit in a communication link.

FIG. 12 shows a second crystal bonded to a first crystal, with the two crystals having differing orientations of packed tetrahedra and differing residual stresses inside.

FIG. 13 shows first, second and third crystals whose differing orientations of packed tetrahedra and residual stresses inside arise from fissures between the crystals.

In FIG. 14, regions of differing orientations of packed tetrahedra and differing residual stresses are separated by small fissures and bubbles within a single crystalline link.

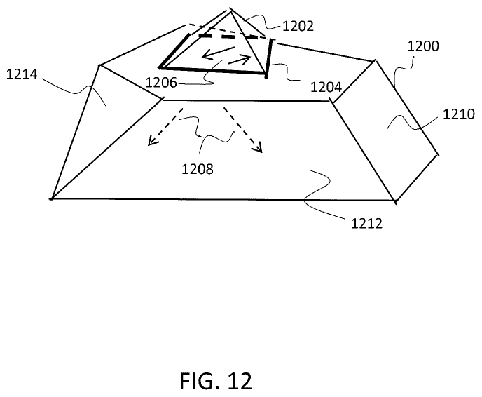

In FIG. 15, which is an expanded view of the interior of FIGS. 12 to 14, a third region of discontinuity separates first and second regions of packed tetrahedra with differing orientations and differing uncoupled strains between the two regions.

### DETAILED DESCRIPTION

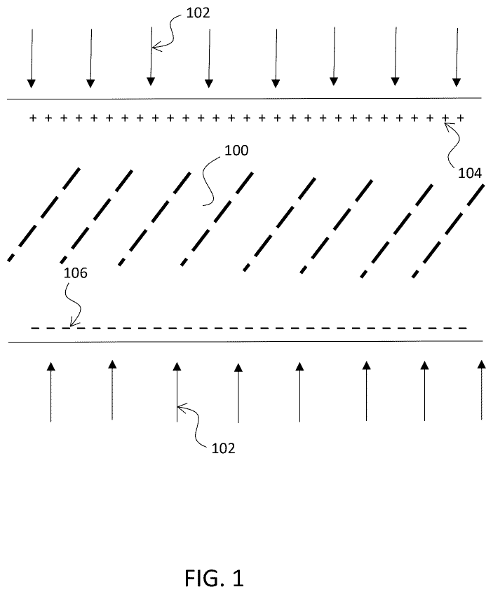

The invention comprises elements shown in FIG. 1. Stress 102 acts on a piezoelectric material 100 to produce a separation of positive charges 104 and negative charges 106. The piezoelectric material 100 is not limited to a particular composition, atomic structure, or granular structure and can be a ceramic or polymer in which positive and negative charges separate to form a voltage under an applied stress. The stress 102, or force per unit area can be static, or dynamic, as in a case in which the stress arrives as a wave upon the device. The positive charges 104 may be the result of holes, or missing electrons, positively charged ions, or atoms within the material lattice with a net positive charge. Similarly, the negative charges 106 may arise from electrons, negatively charged ions, or atoms within the material lattice with a net negative charge.

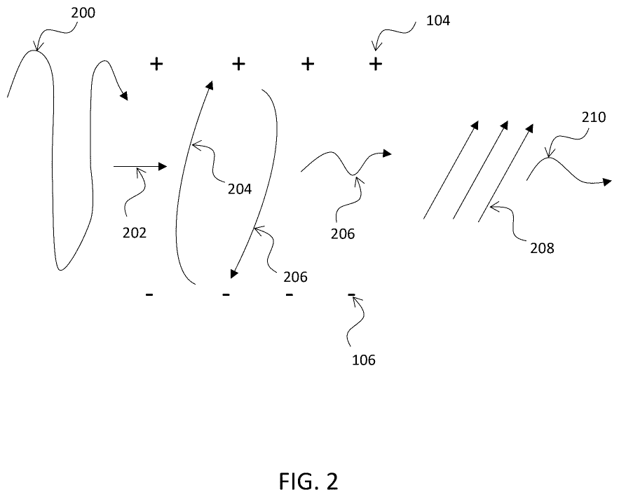

One embodiment has further elements shown in FIG. 2. An incoming wave 200 travels in a direction 202 in a piezoelectric material. Wave 200 promotes oscillation 204 of negative charges 106 that separated and delocalized in the piezoelectric material 100 under stress 102 in FIG. 1. Similarly, wave 200 promotes oscillation or change in angular momentum 206 of positive charges 104 that separated and delocalized in the piezoelectric material 100 under stress 102 in FIG. 1. Oscillations 204 and 206 promote wave 206, which can be further altered by a force field 208 to produce outgoing wave 210. Force field 208 can arise within or outside of material 100. Force field 208 can be electric, magnetic, or mechanical, but is not limited to such forces, and can be any force that can modify an amplitude, frequency, or phase of wave 206.

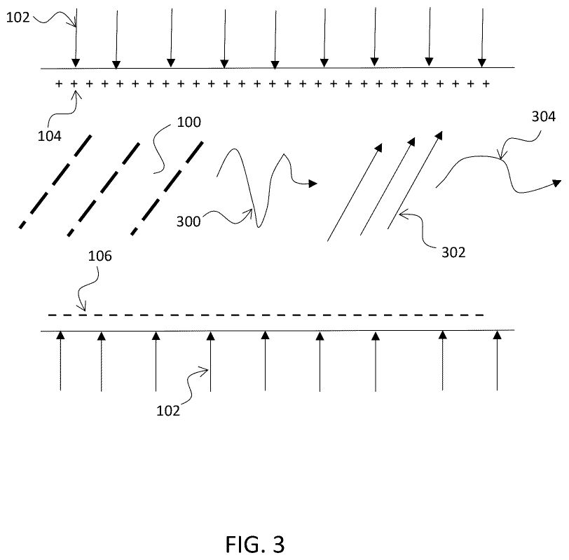

FIG. 3 shows another embodiment in which a wave inside piezoelectric material 100 does not oscillate charges itself but is altered by force fields set up by charges 104 and 106. Again, as in FIG. 2, a static or dynamic load 102 acts upon piezoelectric material 100 to separate positive charges 104 and negative charges 106. Force field 302 can arise within or outside of material 100 and is any force that can alter an amplitude, frequency, or phase of a wave 300 to produce an outgoing wave 304.

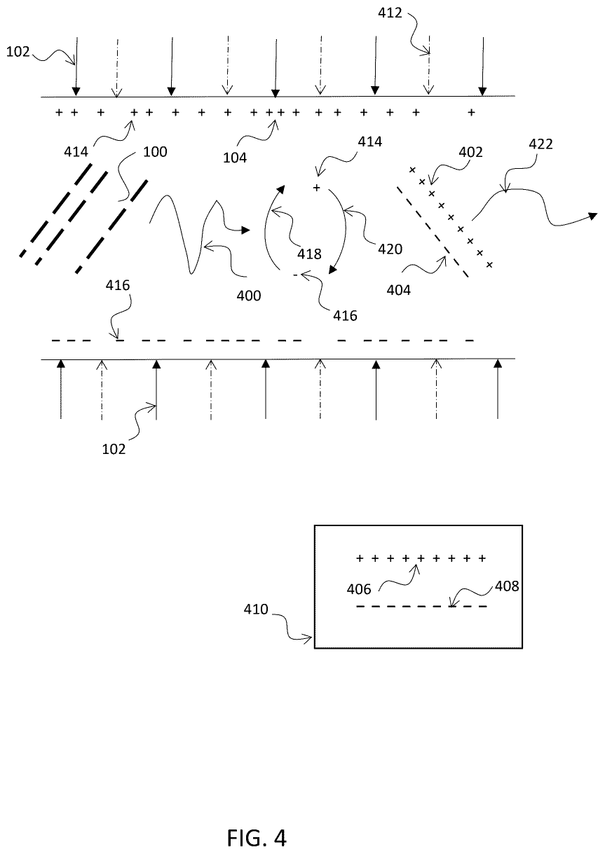

FIG. 4 shows another embodiment in which an initial piezoelectric voltage redistributes itself. The result is accommodation of an optional second applied static or dynamic load that produces a second set of separated charges that oscillate with an incoming wave in piezoelectric material 100 in FIG. 4. Wave 400 is an incoming wave that provides force fields such as electric and magnetic fields that interact with processes occurring inside material 100. Some of the original separated positive charge 104 from load 102 then redistributes to form a set 402 of positive charges and a set 404 of negative charges someplace else on or within piezoelectric material 100. In some embodiments, positive charges 406 and negative charges 408 may be collected and distributed in a region 410 outside of piezoelectric material 100. Whether some of the charges redistribute inside or outside of, or both inside and outside of, piezoelectric material 100, a second static or dynamic load 412 acts upon material 100 to produce separated positive charge 414 and separated negative charge 416. Wave 400 may produce change in angular momentum 418 or oscillation 420 of negative charge 416 or positive charge 414 to produce outgoing wave 422. Alternatively, wave 400 may interact with oscillations 418 and 420 and with any force fields set up by separated charges 402 and 404 to produce outgoing wave 422.

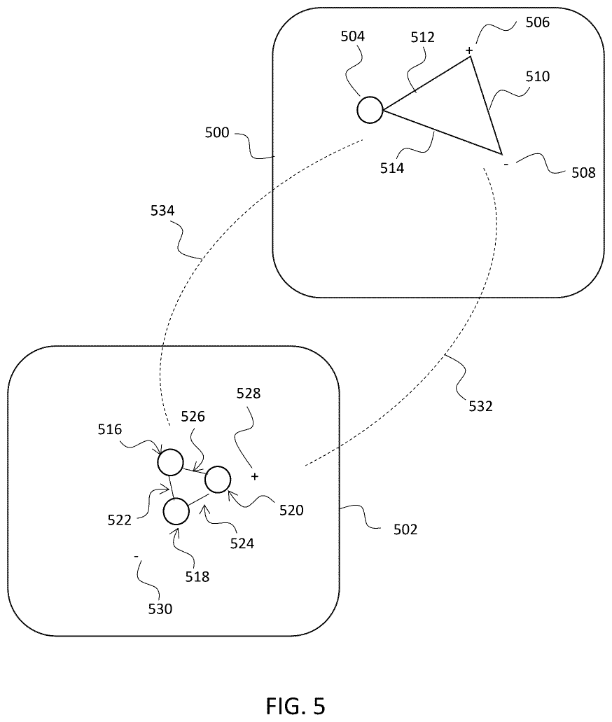

In some embodiments, microstructural elements of piezoelectric material link 500 might interact to form a specific arrangement of microstructural elements of material 502 of an antenna, receiver, or transmitter, as shown in FIG. 5. As it interacts with a mechanical load or signal wave, an atom 504 of material 500 might be near but separate at a microscopic level from a positive charge 506 and a negative charge 508. An interaction between material 500 and a signal wave can arise, for example, from either an oscillating electric field or an oscillating magnetic field of a signal wave. Distance 510 between a positive and negative charge, distance 512 between an atom and a positive charge, and distance 514 between an atom and a negative charge can be different from one another and even change during interaction of material 500 with a signal wave.

In a similar manner, atoms 516, 518, and 520 of antenna, receiver, or transmitter material 502 may be in a particular arrangement connected by bonds 522, 524 and 526, as shown FIG. 5. A positive charge 528 and a negative charge 530 may be separate from each other and from any three atoms 516, 518, and 520. A particular arrangement or displacement of atoms and charges in material 502 can arise from both a signal wave and from an arrangement of atoms and charges in material 500. An interaction 532 between positive and negative charges in material 500 and charges and atoms in material 502 can be present. Similarly, an interaction 534 from a particular arrangement of atoms in material 500 produces a particular arrangement of atoms in material 502. If material 500 is taken away, a particular arrangement of atoms and charges in material 502 from interactions 532 and 534 from material 500 might disappear or remain for some time as material 502 receives or transmits a signal. In one embodiment, material 500 is both piezoelectric and crystalline, and comprises quartz or albite, for example.

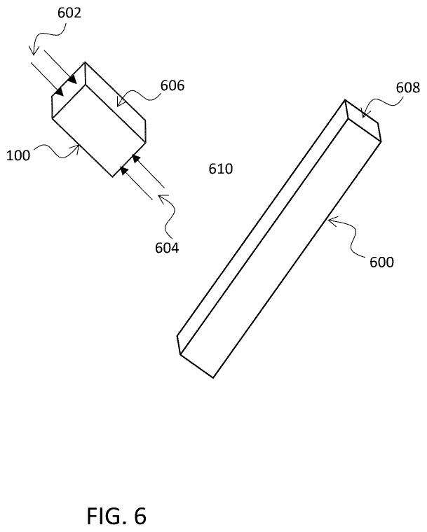

FIG. 6 shows one arrangement of piezoelectric material 100 with an antenna, receiver, or transmitter 600. A piezoelectric mechanical load 602 on one side of material 100 may be the same or different from a mechanical load 604 on another side of material 100 to cause a piezoelectric effect. It is expected that material 100 will not be the uniform rectangular shape shown in FIG. 6, but can have an agglomeration of crystallites, voids, bubbles, crevices, and cracks. Face 606 may be of any shape and may or may not be parallel to any other face. Likewise, the shape of an antenna 600 might not be a rectangular box but could be a thin or narrow strip of material, or any other shape and size of material. End face 608 of antenna 600 may be rectangular, square, circular, spherical or any other shape. End face 608 can be absent if an antenna, receiver, or transmitter 600 is spherical. Material link 100 may be positioned as shown in FIG. 6 or positioned near an end face 608. Distance 610 between material link 100 and antenna, receiver, or transmitter 600 can vary for signal enhancement. Distance 610 can even be zero, making material 100 of a link attached to or embedded into a material of antenna, receiver, or transmitter 600.

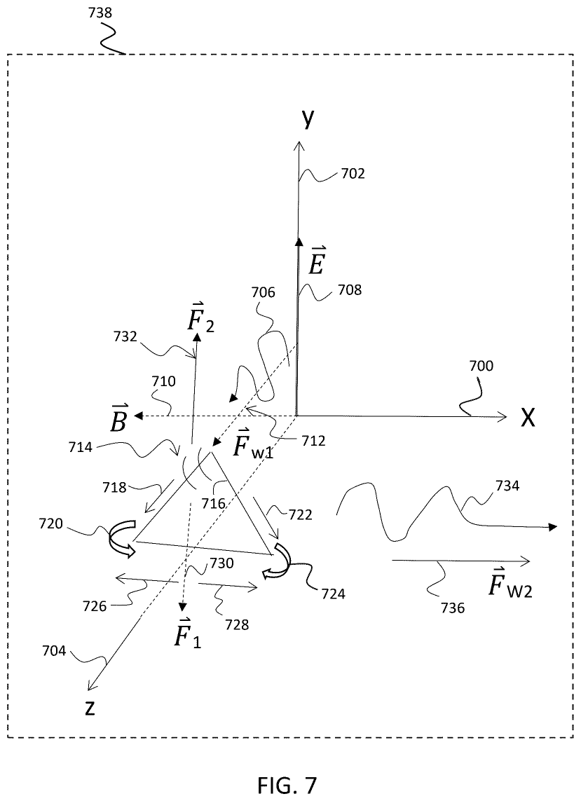

FIG. 7 shows parts of the invention at a microscopic level that may lead to an outgoing signal wave that propagates at an angle to an incoming signal wave. In FIG. 7, propagation and oscillation are with respect to an X axis 700, Y axis 702, and Z axis 704. An incoming signal wave 706 propagates in the z direction. An example of an incoming wave 706 has an electric field [symbol] , labeled 708, that oscillates in the Y direction, a magnetic field 710 that oscillates in the Z direction.

Wave 706 provides a radiation force [symbol] _{w1}, labeled 712, which in turn moves one or more delocalized electrons 714 around part of a microstructural element 716. In FIG. 7, microstructural element 716 outlines a triangle, whose vertices, for example, represent oxygen atoms in a quartz structure. It is to be understood that element 716 can have other shapes that outline atomic arrangements in other materials. Element 716 can also have many different orientations in a material structure. In the example shown in FIG. 7, radiation force 712 could push one or more electrons in direction 718. To remain in an area of delocalization of electrons, one or more electrons could make a change in direction 720. Similarly, electrons could move in direction 722 and make a change of direction 724. If coming upon an electron moving around element 716 from the other side, one or more electrons could even reverse direction, to produce directions of movement 726 and 728.

Acceleration of electrons just described in the last paragraph, depending upon an orientation of element 716, could produce an outgoing signal wave 734 from a material link. Velocity of one or more electrons traveling about element 716 could also interact with an oscillating magnetic field [symbol] , or element 710, to produce both a downward force [symbol] ₁, or element 730, and an upward force [symbol] ₂, or element 732, on an electron. Acceleration of an electron under forces [symbol] ₁ and [symbol] ₂ (elements 730 and 732) could also produce an outgoing signal wave 734. The entire process of a signal wave 706 coming in, an acceleration of delocalized electrons 714 within a material structure itself at a microscopic level, which results in an outgoing 734 is denoted as element 738 in FIG. 7 and will be used in subsequent Figures.

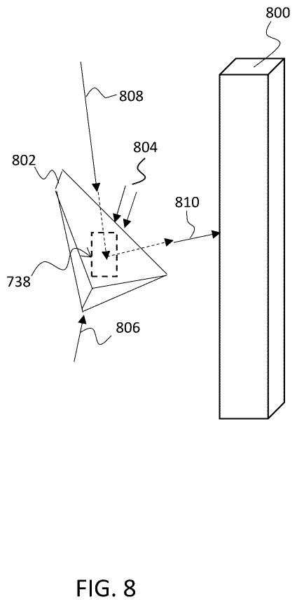

Element 738, with its incoming and outgoing wave, beneficially directs a signal wave to an antenna 800 in FIG. 8. Piezoelectric material 802 has mechanical loads 804 and 806 on it. Mechanical loads may or may not be equal to each other. If material 802 macroscopically has a faceted structure, each load 804 and 806 separately can be on an apex, edge, or face of material 802. Incoming wave 808 interacts with microscopic elements within element 738 to produce an outgoing wave 810. Outgoing wave 810 propagates at an angle to incoming wave 810 to arrive at an antenna 800.

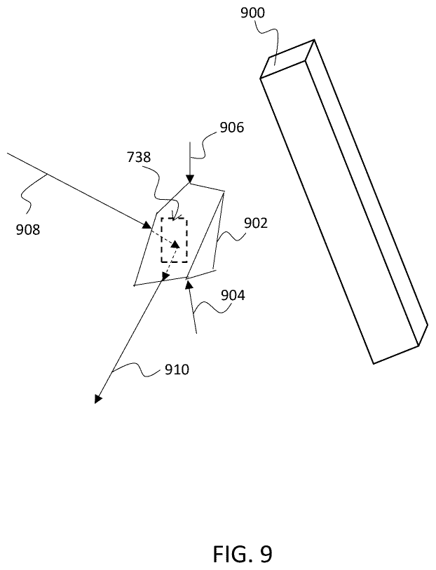

FIG. 9 shows an antenna 900 and a material link 902 that directs signal waves away from antenna 900. Such an arrangement might be beneficial when a material link directs unwanted signals away from an antenna. Stresses 904 and 906 are on material link 902. Stresses 904 and 906 may or may not be equal to each other, and can be compressive, tensile or shear for a localized piezoelectric effect inside material link 902. Incoming signal wave 908 encounters structural components and processes 738 to produce an outgoing signal 910 that is directed away from antenna 900.

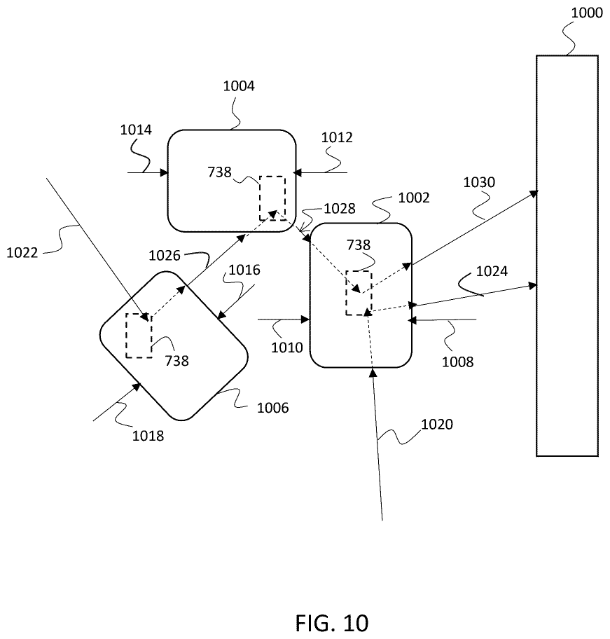

In a system depicted in FIG. 10, antenna 1000 has a trio of material links 1002, 1004 and 1006 nearby. The system of material links 1002, 1004 and 1006 promotes beneficial redirection of signal waves into antenna 1000 when an initial incoming direction of a signal wave is either unknown or can change at any instant. Although FIG. 10 shows a triangular arrangement of material links 1002, 1004 and 1006, an arrangement of material links in this invention can comprise two, three, or a plurality of material links arranged in any shape or in a circle. For a piezoelectric effect, material link 1002 has mechanical loads 1008 and 1010 on its surface. Similarly, material link 1004 has mechanical loads 1012 and 1014 on its surface and material link 1006 has mechanical loads 1016 and 1018 on its surface. Loads 1008, 1010, 1012, 1014, 1016 and 1018 can produce compressive, tensile, or shear stresses, and may or may not be equal to each other.

In FIG. 10, incoming signal wave 1020 shown in the lower right portion of FIG. 10 and incoming signal wave 1022 shown in the upper left portion of FIG. 10 do not have a propagation direction that is optimal to reach antenna 1000. Within material link 1002, Signal wave 1020 meets elements and processes in element 738 shown in FIG. 7 to produce an outgoing signal wave 1024 that propagates at an angle to signal wave 1020 and meets antenna 1000 at a more optimal angle. For incoming signal wave 1022 in FIG. 10, the material links produce more than one outgoing signal wave to reach antenna 1000 at an optimal angle.

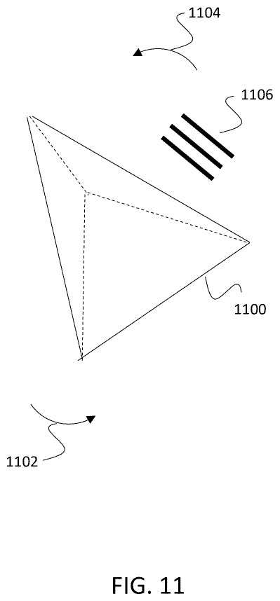

The communication links in this invention have a crystalline microstructure whose atoms outline tetrahedra, such as the SiO4 tetrahedra within quartz. One process that could lead to distortion of tetrahedral arrangements of atoms or electrons within a tetrahedron is shown in FIG. 11. Under stress or force, rotation of a tetrahedral arrangement 1100 leads to two strains 1102 and 1104 on opposite sides of the tetrahedral arrangement that are equal in magnitude. Because the tetrahedral arrangement is non-centrosymmetric, a third uncoupled strain 1106 is present. Both the particular packing of tetrahedra in a crystalline link, along with directions of residual or applied stresses on the tetrahedra produce a pattern of uncoupled strain that is distinct within a particular crystal.

Links that have consistently shown to increase the power of a signal at a receiver by at least 2 dBm and that appear to re-direct a signal wave beneficially are comprised at least two crystals, shown bonded together in FIG. 12. In FIG. 12, crystal 1200 has a second crystal 1202 bonded to it, with a region 1204 between the two crystals that is a boundary between two orientations of packed tetrahedra and their associated patterns of uncoupled strain. In quartz, for example, region 1204 would separate different orientations of helical arrangements of tetrahedra and hence different patterns of uncoupled strain. In other links, region 1204 would separate two orientations of another type of packing of tetrahedra. Residual stresses 1206 in crystal 1202 are likely different from residual stresses 1208 in crystal 1200. Both the change in orientation of tetrahedra across boundary 1204 along with the differing applied or residual stresses 1206 produce in this invention for aiding communication signals differing patterns of uncoupled stress 1106 in the two crystals 1200 and 1202. Boundaries of the regions 1200, 1202 and 1204 can have differing forms and sizes, as shown by a surface 1210 outlined by a rectangle, surface 1212 outlined by a trapezoid, and surface 1214 outlined by a triangle.

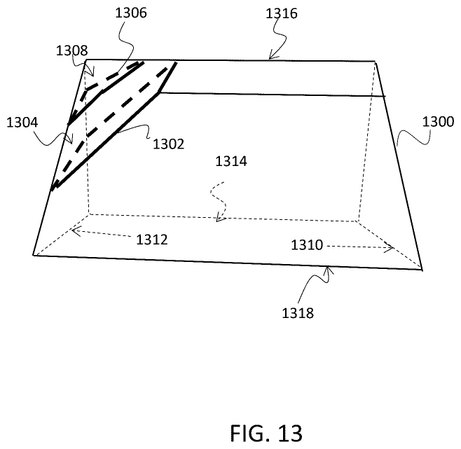

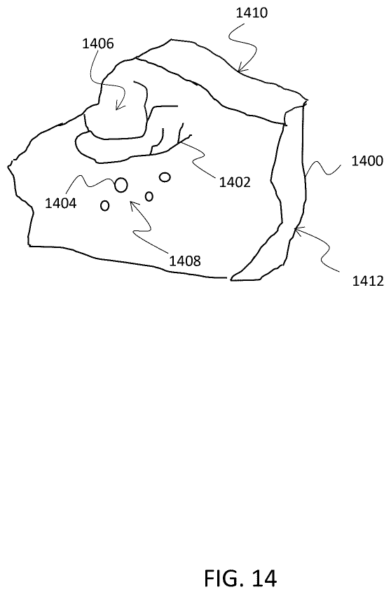

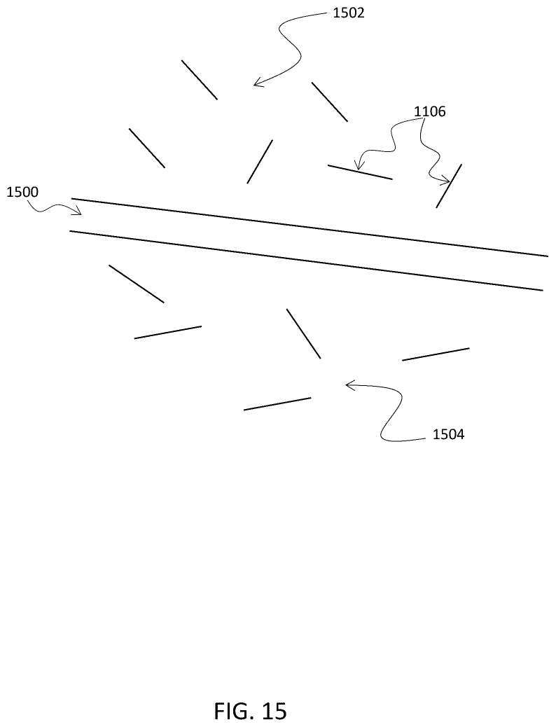

In second embodiment, the region that facilitates a change in orientation of packed tetrahedra and a pattern of uncoupled stresses can be a fissure, as shown in FIG. 13. In FIG. 13, a first region 1300 with an orientation of packed tetrahedra is adjacent to fissure 1302, across which there is a second region 1304 with a second orientation of packed tetrahedra and uncoupled stresses. Region 1304 in turn is adjacent to a second fissure region 1306, across which is a third region 1308 with yet a third orientation of packed tetrahedra and third pattern of uncoupled stresses. Surface boundaries of the three regions 1300, 1304, and 1308 may be outlined by differing shapes from one communication link to another. Regions 1300, 1304, and 1308 in the embodiment in FIG. 13, for example, are bounded by surfaces 1310 and 1312 outlined by triangles and by surfaces 1314 and 1316 outlined by trapezoids.

In a third embodiment, the region between two regions of differing orientations of tetrahedral arrangements and patterns of uncoupled strain need not be planar, as shown in FIG. 14. In FIG. 14, communication link 1400 has a nonplanar fissure 1402 and even bubbles 1404 that separate regions 1406 and 1408 that will have different orientations of tetrahedra and patterns of uncoupled strain between them. Surfaces 1410 and 1412 at the boundaries of communication link 1400 are either curved or are a series of small facets so that surfaces 1410 and 1412 are nonplanar in a macroscopic sense.

FIG. 15 shows an expanded view of two material regions with differing orientations of packed tetrahedra. Region 1500 is a disruption in bonding between two regions 1502 and 1504. Computer simulations have shown that the size and spacing of regions of uncoupled strain, along with the magnitude of uncoupled strains themselves, differ greatly between two orientations of two tetrahedra along a helix within a quartz structure. Regions 1106 of uncoupled strain from FIG. 11 are shown again in FIG. 15 as differing patterns of uncoupled strain within regions 1502 and 1504 and across region 1500. Differing patterns of uncoupled strain that may delocalize electrons to promote communication signals may be static or dynamic under one or more static or dynamic loads on the communication link.

Although particular embodiments of the invention have been described in detail herein with reference to the accompanying drawings, it is to be understood that the invention is not limited to these precise embodiments, and that various changes and modifications may be effected therein by one skilled in the art without departing from the scope or spirit of the invention as defined by the appended claims.

What is claimed:

1. A crystalline piezoelectric material link to reduce communication signal loss, wherein said material link comprises an electric field that arises from positive and negative charges that separate under a load applied to said material link; an oscillation of said charges; and an alteration of amplitude of an incoming signal wave by said electric field and said oscillation to produce an outgoing signal wave.

2. The crystalline piezoelectric material link of claim 1, wherein said load arises from one or more static loads.

3. The crystalline piezoelectric material link of claim 1, wherein said load arises from a wave.

4. The crystalline piezoelectric material link of claim 1, wherein said load arises from an electric or magnetic field.

5. A crystalline piezoelectric material link for communication signals, wherein said material link comprises a first voltage that arises from a load applied to said material link; a second voltage that arises from a redistribution of charges that form said first voltage; an incoming wave that further comprises a force that oscillates charges of said first or second voltages; and an outgoing wave that arises from said oscillations of said charges.

6. The crystalline piezoelectric material link of claim 5, wherein said load arises from one or more static loads.

7. The crystalline piezoelectric material link of claim 5, wherein said load arises from a wave.

8. The crystalline piezoelectric material link of claim 5, wherein said load arises from an electric or magnetic field.

9. A communication link system that comprises a non-centrosymmetric crystalline structure of packed tetrahedra under a load, wherein said crystalline structure further comprises a first region with a first orientation of packed tetrahedra and a first pattern of uncoupled strain, a second region with a second orientation of packed tetrahedra with a second pattern of uncoupled strain, a third region between said first and said second regions, wherein said third region comprises a change in orientation of tetrahedra or a fissure; and wherein said communication link structure further comprises an antenna or transceiver that further comprises a configuration of atoms and charges that is a result of an interaction with said first and second patterns of uncoupled strain within said non-centrosymmetric crystalline structure of packed tetrahedra.

10. The communication link system of claim 9, wherein said load arises from one or more static loads.

11. The communication link system of claim 9, wherein said load arises from a wave.

12. The communication link system of claim 9, wherein said load arises residual stresses within said crystalline structure.
